(19) United States
(12) Patent Application Publication
(10) Pub. No.: US 2003/0197133 A1
(43) Pub. Date: Oct. 23, 2003

(54) Method and apparatus for scanning a workpiece in a vacuum chamber

(76) Inventors: Norman L. Turner, Vero Beach, FL (US); Kenneth H. Purser, Lexington, MA (US)

Correspondence Address: Henry C. Nields, Nields & Lemack, Suite 7, 176 E. Main Street, Westboro, MA, 01581, US

(21) Appl. No.: 10/418,366

(22) Filed: Apr. 18, 2003

Related U.S. Application Data
(60) Provisional application No. 60/375,169, filed on Apr. 23, 2002.

(51) Int. Cl. H01J 37/20

(52) U.S. Cl. 250/492.21; 250/442.11

(57) ABSTRACT

An apparatus for controlling the motion of a workpiece in a vacuum chamber. The work piece is supported in vacuum on a pedestal or platen, containing an electrostatic chuck for holding and clamping the workpiece.

The platen is supported by a shaft extending through the wall of the vacuum chamber. The shaft moves back and forth (reciprocates) along its length (x axis) to accomplish scanning, and rotates about this axis to allow variable workpiece positioning during treatment as well as rotation of the platen to the horizontal position for workpiece exchange.

Vacuum integrity is maintained by a series of mechanical seals, guide bearing, and differential pumping. The shaft is supported in atmosphere by guide bearings on a track, and driven back and forth by a linear motor. A second motor provides shaft rotation.

### FIELD OF THE INVENTION

The present invention relates to devices for providing individual workpieces such as silicon wafers or flat panel displays to be positioned for processing in vacuum by a treatment beam.

### BACKGROUND OF THE INVENTION

Process typically done on silicon wafers in semiconductor manufacturing including subjecting the target material to energetic beams such as ion beams, molecular beams, plasmas, etc. In most cases, uniform processing of all the surface area of the workpiece is essential. Typical uniformity of process is ±1%, therefore special considerations for uniform application of the irradiating element as well as the positioning and motion of the target is essential. Further, more exotic requirements to place implants through mask windows at a steeper than 7 degrees has precluded the use of batch processing which does not allow wafer tilt control beyond 10 degrees. Recent requirements have implant beam to target angles as high as 60 degrees, requiring a new generation of target (wafer) control mechanisms.

In earlier ion implantation techniques, various methods of moving an ion beam over a stationary target, or moving a batch of targets mounted on the periphery of a spinning disk through a stationary ion beam, was a common solution. More recently, since wafer sizes have grown to 300 mm diameters, mechanical scanning these large targets through stationary beams has become undesirable due to equipment size and cost. In addition, larger wafers sizes have pushed semiconductor manufacturing away from batch processing of wafers to individual, one at a time processing.

The combination of high dollar value per wafer, along with individual process control requirements, and a smoother flow of work through the factory, have made single wafer processing the dominant processing method in modern 300 mm wafer processing factories.

For the ion implantation process, some equipment manufacturers have achieved uniform implantation of large wafers, by forming a uniform ion beam which is wider than the target or wafer (sometimes called a ribbon beam) and then scanning the wafer through the uniform ribbon beam, back and forth, to accomplish uniform implantation of a single large wafer. Methods of forming these ribbon ion beams are discussed in U.S. Pat. Nos. 5,834,786 and 5,350,926. Systems for mechanically scanning a single wafer through a wide ribbon beam have been built and described in the patent and references of U.S. Pat. No. 5,898,179, Smick et al. In the systems built to date, wafer scanning has been at near vertical, or an up and down motion, passing the wafer through a horizontal or near horizontal ribbon beam. The above-mentioned patent utilizes an air bearing slider to effect the scan motion and a separate rotating motion for target orientation and loading.

In another embodiment, vertical scanning was achieved, by a vertical reciprocating shaft, and required a second horizontal axis and motor, to change the wafer process angle and tilt down to the exchange position. In the present invention, the scanning and rotation occurs horizontally, allowing both target scanning and rotation to utilize the same shaft and vacuum seal, therefore simplifying system cost and complexity. It also requires a uniform ion beam whose wide dimension is vertically oriented.

### SUMMARY OF THE INVENTION

The present invention provides a method of positioning a target to a high tilt angle, uniformly scanning the target through a ribbon shaped beam (fixed or scanned) and exchanging the target in vacuum. The features of the invention are:

(1) A workpiece holder or platen with an electrostatic chuck mounted on one end of a rod shaped arm in the horizontal x-axis in vacuum.

(2) A differentially pumped vacuum seal on the arm, which maintains vacuum integrity, guided by a bearing which is allowed to float such that shaft alignment to the chamber is not critical and smooth scanning arm motion is allowed.

(3) An arm support bearing assembly in atmosphere having the ability to move the arm along its length axis (x) back and forth for scanning and rotate about the x-axis to allow target positioning implant angle, and allow movement from the implant or process position(s) to the target exchange position (usually at or near horizontal).

(4) A pair of drive motors, one for control of x-axis scanning motion and the other for target tilt position control.

In one aspect of the present invention, there is a shaft extending through the sidewall of the vacuum chamber having on its vacuum side a platen or workpiece pedestal containing an electrostatic chuck for clamping the workpiece. With the platen in the near horizontal position, an array of pins is brought through holes in the platen so as to allow easy target exchange in vacuum by a robotic arm. With the platen in this horizontal position, the vacuum robot places the target or wafer to be processed on the pins. After the robot arm retracts clear of the platen, the pins with their drive mechanism lower the wafer onto the platen and continue lowering until pin assembly is clear of the platen and its support arm. Upon energizing the electrostatic chuck, the arm rotates (or twists) about its length, moving the target to the vertical or near vertical (tilt angle) position for processing. The shaft extends through the sidewall of the vacuum chamber through a differentially pumped seal. In this aspect of the invention, this seal, with its precision guide bearing to maintain concentricity of the seal to the shaft, are non-constraining and allow for some shaft misalignment or translation during scanning or tilting of the shaft. In atmosphere, the shaft is held by a bearing block, which allows shaft rotation. The block provides shaft support to precision slide bearings on a rigid mounted track that allows shaft motion horizontally though the vacuum chamber sidewall for scanning the workpiece through the beam. The bearing block is driven by a linear motor capable of moving the mass at speeds of up to several hertz. In another embodiment of this scan mechanism, energy storing devices such as springs or air cylinders are used to facilitate rapid de-acceleration and acceleration at the end of the stroke to reduce the high force required by the linear drive motor. To facilitate platen rotation for process angle tilt and target exchange, a rotary motor mounted on the bearing block drives the shaft in rotation. This motor moves with the bearing block during target scanning.

It should be recognized that the purpose of the invention is to allow rapid movement of the target through a vertically shaped beam, passing the entire target or wafer from one side of the beam completely to the other side of the beam. The vertically shaped beam could be a stationary fanned out or parallel beam, or a rapidly scanned spot beam scanned rapidly up and down to affect a ribbon beam shape.

Mechanically scanning the wafer through the beam is necessary to minimize wafer heating (in the case of high power beams) as well as reducing beam induced charging effects.

Position of the wafer in its tilt to the beam, i.e., the angle of the incident incoming ions to the wafer surface, is important in some cases to control ion channeling. Those skilled in the art recognize channeling avoidance angles both axially and rotationally must be able to be preset as a critical implant parameter.

### BRIEF DESCRIPTION OF THE DRAWINGS

FIG. 1 is a diagram showing an ion implant chamber in accordance with the present invention;

FIG. 2A is a detail view of the target platen and scan drive mechanism in the scanned position;

FIG. 2B is a detail view of the target platen and scan drive mechanism in the wafer exchange position; and

FIG. 3 is a view of the self-aligning differentially pumped shaft seal.

### DETAILED DESCRIPTION OF THE PREFERRED EMBODIMENTS

The preferred invention is used for scanning large diameter wafers typically 200 or 300 mm diameter through ion beams for the purpose of ion implantation. It should be recognized however that this same invention could be well suited for other processes using target scanning through any energetic beam, and that not only round wafers but flat panel glass or other shaped materials could be processed.

In order to control the ion implant process, an ion beam is directed toward the implant chamber. The beam must be made to be elongated uniformly across the wafer diameter. This beam may be formed by a fanned out fixed beam, or a fixed parallel ±1 degree beam, or a spot beam scanned linearly up and down at a rapid rate (>100 Hz) to emulate a fixed ribbon shaped beam. In order to ensure uniform dosing across the wafer, both the fixed or scanned beam uniformity must be controlled to be uniform as well as the mechanical scan rate of the wafer through the beam. In order to control beam uniformity and linearity, a beam measuring system is provided. Compensation and adjustment of beam uniformity done in the beam transport system is known in prior art.

In order to control the total dose received by the wafer, the present invention provides a beam faraday, which measures the total beam current in the beam prior to the start of the implant. A dose control computer calculates the number of scans of the wafer through the beam in order to achieve the desired total dose. The rate of each scan is preset but updated at the start of each scan cycle based on the measured beam current at that time. Beam current can be measured at the beginning or end of each scan cycle, while the target is off the beam in the over scan area, by a linear shaped faraday cage (8). At that time the scan rate given to the linear drive motor can be reset for each scan, thereby ensuring each scan is a correct scan rate for the beam current measured. For beams which are not steady and are varying, the system will average out these variations by controlling each scan cycle rate, and overall dose will be controlled and accurate within most processing requirements.

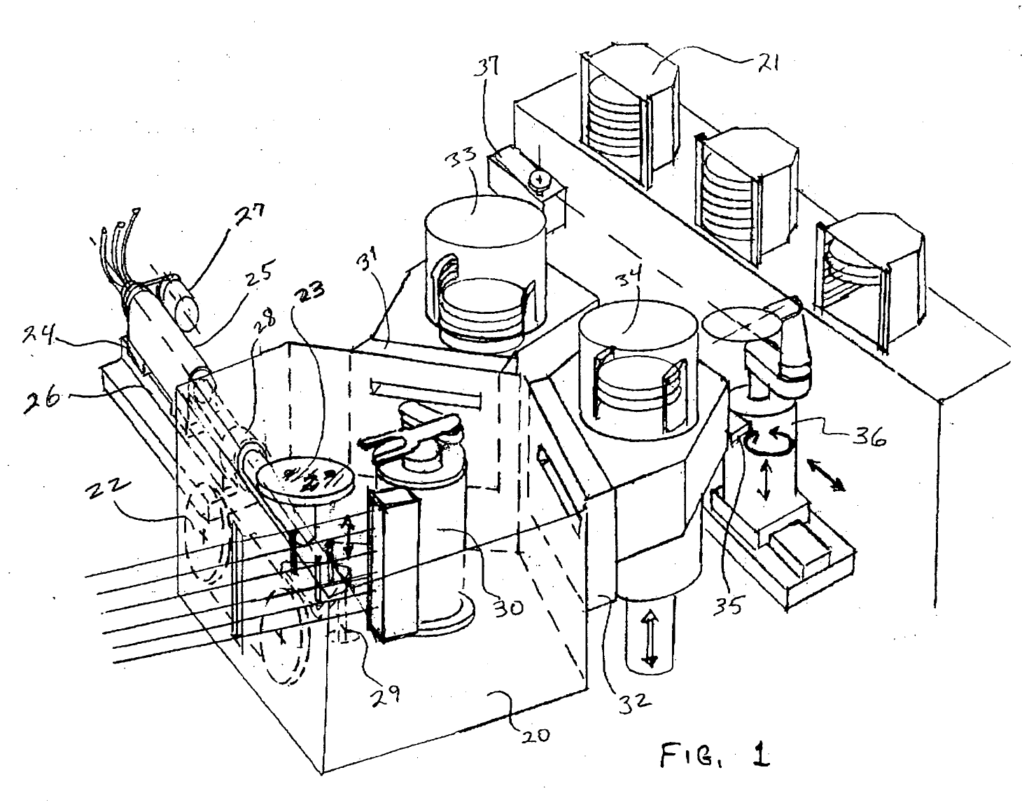

In FIG. 1, the implant chamber (20) can be seen fitted with the main elements to facilitate loading targets from atmosphere carriers (21) into the vacuum system, ion implanting the targets in a uniform controlled manner, and returning them to their original carrier.

The wafer scanning mechanism drives the platen (22) holding the wafer, (23) back and forth through the beam at a linear velocity between 0.3 to 5.0 meters per second. At the ends of each scan when the wafer has passed the narrow dimension of the beam, the platen drive system (24) returns the velocity to zero and reaccelerates it to the original velocity in the opposite direction.

In FIG. 1 it can be seen that the scan drive or platen drive system consists of a linear support bearing (25), a linear drive motor (26), and a platen tilt motor (27). These elements provide mechanical support, scanning and tilting of the platen (22), during implantation and wafer exchange. A low-friction vacuum seal mechanism (28) using differential pumping and guided bearing, maintains the vacuum integrity of the implant chamber. The platen rotational motor (27) allows implantation at almost any angle between ±60 degrees. With the platen rotated to the horizontal position, as is shown in FIG. 1, the electrostatic field is turned off to allow the wafer to be lifted by the lift-pin array (29) whose purpose is to raise the wafer above the platen for removal and exchange by the vacuum robot (30). It will be clear to those skilled in the art that a dual arm vacuum robot could be substituted to improve wafer throughput. From FIG. 1, we can see that the vacuum robot is positioned to allow access though the vacuum isolation slot valves (31), (32), to access two (or more) vacuum load-locks, (33), (34). By having two load-locks, vacuum wafer processing and exchange can occur in one load-lock while atmospheric pressure wafer exchange takes place, simultaneously in the other. This geometry ensures continuous processing of wafers and is consistent with throughputs of approximately 180 wafers per hour.

The dual load-locks utilize dedicated cassettes with vertical Z-motion to facilitate slot access for wafer insertion and removal by the vacuum robot. The number of slots in the dedicated cassettes is typically 10, but those skilled in the art will recognize that the number of slots can be more or less and is dictated by the minimum implant time.

The load-locks are also fitted with an atmospheric closure valve (35) that allows access during wafer exchange for an atmospheric robot (36). When closed, these valves allow said load-locks to be pumped down for vacuum exchange. In the preferred arrangement, an atmospheric robot can exchange wafers from the open load-lock to the users cassettes and reload the load-lock with new wafers to be implanted. In addition, a wafer notch finder (37) can be used to orient the wafer so that the crystal alignment with the beam is placed so as to reduce planar channeling.

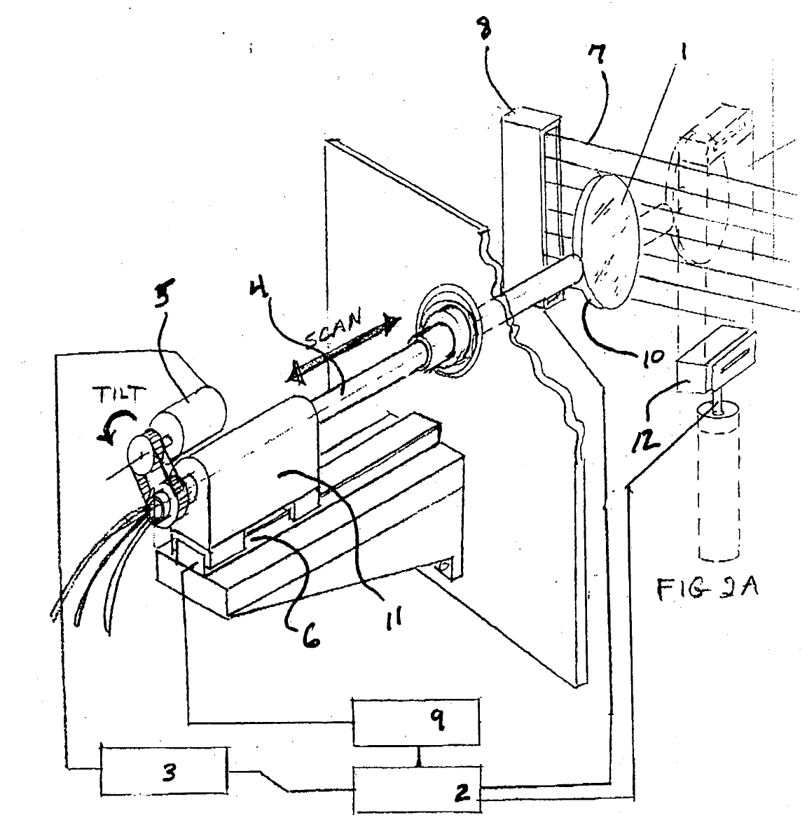

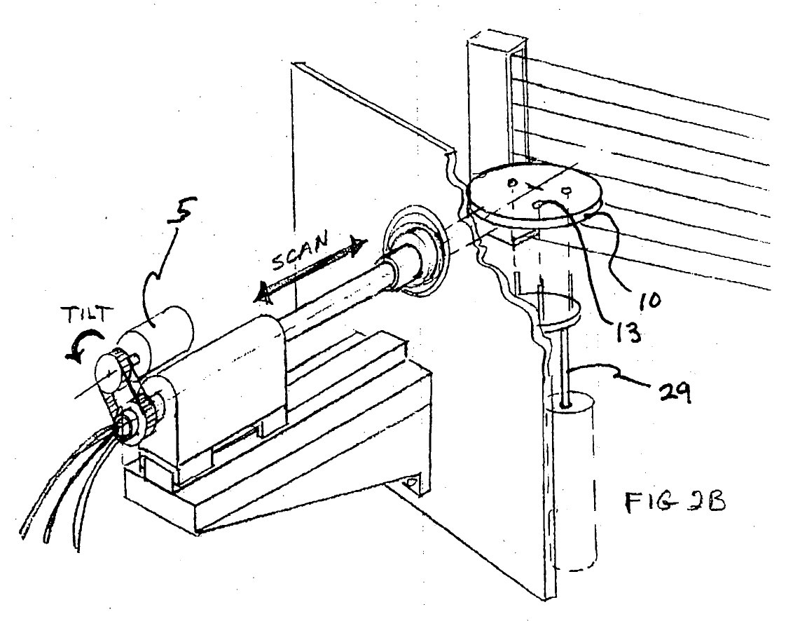

FIG. 2A shows the preferred system during target scanning through the beam. FIG. 2B shows the platen tilted horizontally for exchanging wafers.

In FIG. 2A we can see the wafer in a preset tilt position scanning though the beam. The tilt angle, that angle between the wafer surface and the incoming ion beam may be preset in the process control computer (2) to angles from 0 to ±60 degrees. The control computer gives the proper command to the tilt motor drive (3) which rotates the tilt motor (5) causing the shaft (4) to rotate about its scan axis until a feed back encoder verifies the tilt angle has been achieved. Scanning through the beam is facilitated by a scan drive motor and bearing track (6), allowing for a smooth scan motion and length to pass the wafer completely through the beam (7), from one side to the other. For a 300 mm wafer and a 50 mm wide beam, the scan travel would be at least 400 mm. After beam setup (discussed later) and the beginning of the implant, the process control computer (2) receives the dose requirement from a higher level process control and presets the total number of scans based on the amplitude of the beam current measured in the faraday (8) beam collector and the required dose. Each scan cycle complete 1/nth of the dose based on the number of scans (n) computed. The maximum number of scans thereby requiring a high scan rate motor is preferred so as to minimize ion beam heating of the wafer and to reduce wafer charging effects.

After calculating the number of scans, the scan rate is set at each scan cycle by measuring the beam current when the platen is fully retracted at the end of each scan cycle. A current integrator connected to the faraday measures the ion beam. The computer samples the faraday current during the scan turn around for about 10 ms, and sets the scan rate of the next scan cycle by way of the scan drive electronics (9), which controls the scan drive motor (6). All the platen components (10), shafts (4), shaft support bearing (11), and drive motor (6) are optimized for low mass and high strength. For faster scanning, with rapid acceleration, low mass components are essential for high scan speeds. The platen support shaft (4) is tubular for lightweight, and allows coolant lines and electrical connections to the platen.

As conventionally known in the art, the workpiece holder or platen (10) has an electrostatic chuck for holding silicon wafers and is coated with a polyamides or other electrically insulating thin material. A series of holes feed gas such as H2 or He2 or N2 to the gap between the wafer and the platen for improved heat flow from the wafer to the platen itself. A liquid coolant is flowing through channels in the platen base for removal of the heat and maintaining the platen at a low base temperature, typically <20 degrees C.

In order to further facilitate rapid scan rates and turn around, other devices can be used for balancing the force of vacuum by applying a constant force on the scan shaft along its axis. The force is about 1 atmosphere times the area of the shaft. For a practical size shaft of 60 mm diameter, this force is approximately 10 Kg. This force, due to vacuum, if not compensated, would cause the scan motor drive current to be higher when the platen was retracting in the vacuum chamber and lower when the platen was extending. To balance the force of vacuum on the scan system, one of several devices could be used (not shown); a vacuum cylinder attached at one end to the chamber, and the rod end to the scan drive with a vacuum line to the chamber attached to the cylinder. The cylinder diameter would be sized to match the size of the scan shaft. Whenever vacuum was present in the chamber and the cylinder, the force on the scan drive would be neutralized. Other devices such as pressurized cylinders and/or mechanical constant force springs could be used, but the vacuum cylinder is preferred due to its failsafe nature and simplicity of control.

Referring to FIG. 2A, prior to implant, a beam uniformity check may be required. Item 12, a beam scanning faraday can be moved across the length of the beam connected to the current integrator so as to measure and map the linearity of the beam. In memory, a map of intensity vs. position can be made. It must be recognized by those skilled in the art that beam adjustment elements could be affected so as to improve any measured non-uniformity, and after beam adjustment, another beam scan could be done for verification of a uniform beam.

After the implant is completed, the control system and the scan drive motor will be in the retracted position shown in FIG. 2B. The platen (10) is tilted to the horizontal position by actuation of the tilt motor (5). The electrostatic force will be removed from the platen and the cooling gas flow stopped so that no lateral wafer motion occurs. The lift pin assembly (29) will then extend up so that its pins pass though clearance holes (13) in the platen, causing the wafer to be raised above the platen surface enough to provide clearance for the vacuum robot arm (see FIG. 1) or end effector to pick up the wafer and replace it with the next workpiece for processing. After the new workpiece or wafer is placed on the pins and the robot arm retracted, the pin assembly (29) is lowered and the platen electrostatic chuck is energized and the coolant gas allowed to flow. The platen is now tilted to the prescribed tilt position shown in FIG. 2A. for the beginning of the implant process described earlier.

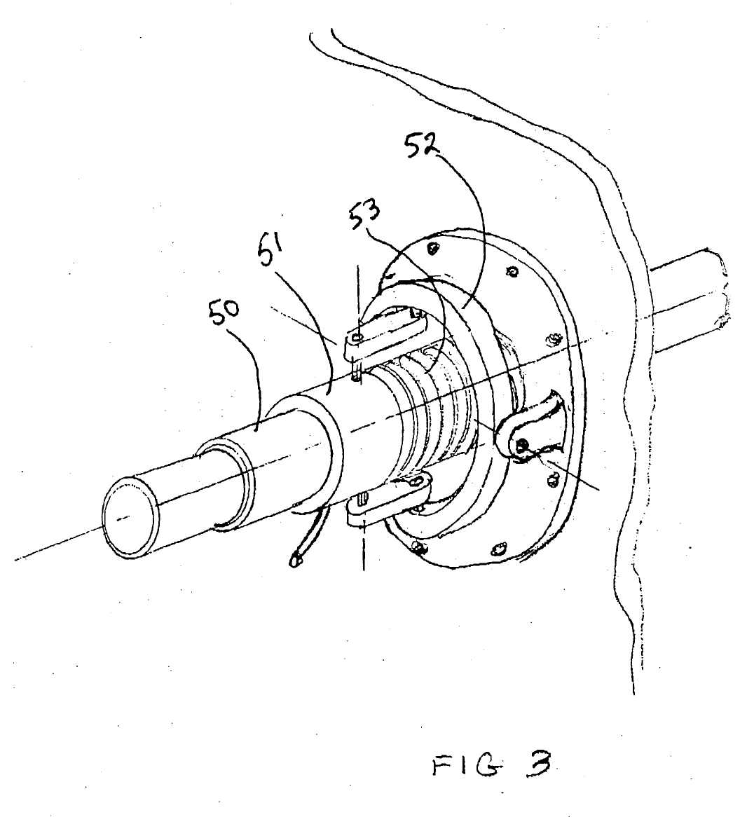

In order to minimize friction in the scan drive shaft the vacuum seal, FIG. 3, shows the guided differentially pumped seal. The scan drive shaft is a hard-coated chrome tube with a polished surface to 4 Ra roughness. The guide bearing (50), and housing, supports a multi-labyrinth vacuum seal (51) around the shaft with a tight positive clearance. The bearing and seal housing are mounted via a gimbal (52), allowing the alignment of the seal over the shaft to be maintained. The vacuum bellows (53) maintains vacuum integrity and insures freedom of the guide bearing and seal to float on the shaft, eliminating any binding and the need for perfect alignment and rigid chambers.

It would be appreciated that the present invention could utilize a duplicate scan drive and platen system on the opposing side of the vacuum chamber and as such, a very high throughput system for short implant times would result. Throughputs for 10 second implants with the dual platen system, would exceed 300 wafers per hour.

What is claimed is:

1. Apparatus comprising a vacuum chamber having walls and a treatment region within said chamber, one of said walls having an aperture, a shaft extending through said aperture, a platen adapted to hold a workpiece, said platen being supported upon that portion of said shaft which lies within said vacuum chamber, and means for imparting rotary and longitudinal motion to said shaft, whereby a workpiece held by said platen may be scanned through said treatment region, the tilt thereof in the treatment region may be adjusted, and workpiece exchange may be effected.

2. Apparatus in accordance with claim 1, wherein said longitudinal motion is reciprocating.

3. Apparatus in accordance with claim 2, wherein a self-aligning floating seal, which is differentially pumped, is provided in said aperture, thereby allowing said shaft both to rotate and to reciprocate.

4. Apparatus in accordance with claim 2, wherein rotation of the reciprocating shaft controls and sets the processing angle and as well rotates the workpiece to an exchange position.

5. Apparatus in accordance with claim 2, wherein said treatment region is a ribbon-shaped ion beam.

6. Apparatus in accordance with claim 1, wherein said walls have at least two apertures providing access to at least two vacuum load-locks for wafer exchange.

7. Apparatus for implanting ions into a workpiece, comprising a vacuum chamber, means for directing a ribbon-shaped ion beam into said vacuum chamber, and scanning means for scanning a workpiece through said ion beam, said scanning means for comprising a shaft extending into said vacuum chamber through an aperture, a platen adapted to hold a workpiece, said platen being supported upon that portion of said shaft which lies within said vacuum chamber, and means for imparting rotary and longitudinal motion to said shaft, whereby a workpiece held by said platen may be scanned through said treatment region, the tilt thereof in the treatment region may be adjusted, and workpiece exchange may be effected.

8. Apparatus in accordance with claim 7, wherein said ribbon-shaped ion beam is vertically oriented and wherein said shaft extends horizontally into said vacuum chamber.

9. Apparatus comprising a vacuum chamber, a shaft extending into said vacuum chamber, support means on said shaft within said vacuum chamber adapted to support a workpiece, and means for imparting longitudinal and rotary motion to said shaft.

10. Apparatus in accordance with claim 9, wherein said shaft extends horizontally into said vacuum chamber, and wherein during workpiece exchange said shaft can be rotated so that said workpiece can be held in a horizontal position by the force of gravity alone.
